(19) United States
(12) Patent Application Publication
(10) Pub. No.: US 2026/0273591 A1
(43) Pub. Date: Sep. 17, 2026

(54) SUBSTRATE PROCESSING APPARATUS, PIPE WITH MEASURING DEVICE, AND MEASURING METHOD

(71) Applicant: Kioxia Corporation, Tokyo (JP)

(72) Inventor: Shota ISHIKAWA, Yokkaichi (JP)

(73) Assignee: Kioxia Corporation, Tokyo (JP)

(21) Appl. No.: 19/332,680

(22) Filed: Sep. 18, 2025

(30) Foreign Application Priority Data
Mar. 14, 2025 (JP) 2025-041205

(51) Int. Cl. B08B 9/032; B08B 7/00; G01B 7/06; H01L 21/67

(52) U.S. Cl. CPC B08B 9/0325; B08B 7/0035; G01B 7/085; H10P 72/0402; B08B 2209/032

(57) ABSTRACT

According to one embodiment, a substrate processing apparatus includes a processing container that processes a substrate, a gas supply pipe that supplies a processing gas to the processing container, a pump that evacuates an atmosphere in the processing container, an evacuating pipe that connects the processing container and the pump, one or more pairs of conductive terminals, and a measuring device that is one of an electrostatic capacitance measuring device, a frequency counter, or a resistance value measuring device. A first end portion of each of the one or more pairs of conductive terminals is inserted into the evacuating pipe. The measuring device is connected to a second end portion of the conductive terminal outside the evacuating pipe.

### CROSS-REFERENCE TO RELATED APPLICATION

This application is based upon and claims the benefit of priority from Japanese Patent Application No. 2025-041205, filed Mar. 14, 2025, the entire contents of which are incorporated herein by reference.

### FIELD

Embodiments described herein relate generally to a substrate processing apparatus, a pipe with a measuring device, and a measuring method.

### BACKGROUND

In a manufacturing step of a semiconductor apparatus, processing using a processing gas may be performed on a substrate. At this time, a predetermined product generated by a reaction of the processing gas or the like may be deposited in an evacuating pipe for evacuating the atmosphere in a processing container. When such a deposition film is left, there is a risk that the deposition film may peel off from an inner wall of the evacuating pipe and damage a pump or the like. Therefore, it is desired to measure a thickness of the deposition film with high accuracy and simplicity.

### DESCRIPTION OF THE DRAWINGS

FIG. 1 is a cross-sectional view schematically showing an example of a configuration of a processing container provided in a substrate processing apparatus according to an embodiment.

FIG. 2 is a schematic diagram showing an example of a configuration of an evacuating system provided in the substrate processing apparatus according to the embodiment.

FIGS. 3A and 3B are schematic diagrams showing an example of a configuration of a film thickness meter according to an embodiment.

FIGS. 4A to 4C are schematic diagrams showing an operation principle of the film thickness meter according to the embodiment.

FIG. 5 is a schematic perspective view showing an example of a configuration of a pipe with a measuring device to which the film thickness meter according to the embodiment is attached.

FIGS. 6A and 6B are schematic diagrams showing an example of a configuration of a film thickness meter according to Modified Example 1 of the embodiment.

FIGS. 7A to 7F are schematic diagrams showing an operation principle of the film thickness meter according to Modified Example 1 of the embodiment.

FIGS. 8A and 8B are schematic diagrams showing an example of a configuration of a film thickness meter according to Modified Example 2 of the embodiment.

FIGS. 9A to 9C are schematic diagrams showing an operation principle of the film thickness meter according to Modified Example 2 of the embodiment.

FIGS. 10A and 10B are schematic diagrams showing an example of a configuration of a film thickness meter according to Modified Example 3 of the embodiment.

FIGS. 11A and 11B are schematic diagrams showing an example of a configuration of a cleaning unit according to Modified Example 4 of the embodiment.

### DETAILED DESCRIPTION

Embodiments provide a substrate processing apparatus, a pipe with a measuring device, and a measuring method capable of measuring a thickness of a deposition film with high accuracy and simplicity.

In general, according to one embodiment, a substrate processing apparatus includes a processing container that processes a substrate; a gas supply pipe that supplies a processing gas to the processing container; a pump that evacuates an atmosphere in the processing container; an evacuating pipe that connects the processing container and the pump; one or more pairs of conductive terminals, one end portion of each of which is inserted into the evacuating pipe; and an electrostatic capacitance measuring device, a frequency counter, or a resistance value measuring device, which is connected to the other end portion of the conductive terminal outside the evacuating pipe.

Hereinafter, the present disclosure will be described in detail with reference to the drawings. The present disclosure is not limited to the following embodiments. The elements in the following embodiments include those that can be easily assumed by those skilled in the art of those that are substantially the same.

### Configuration Example of Substrate Processing Apparatus

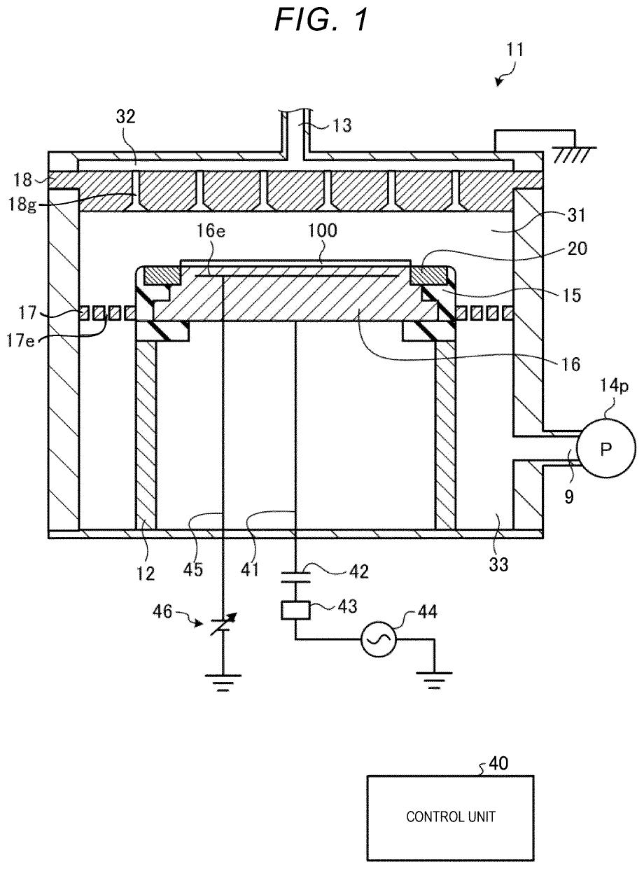

FIG. 1 is a cross-sectional view schematically showing an example of a configuration of a processing container 11 provided in a substrate processing apparatus 1 according to an embodiment. The processing container 11 is configured to be capable of film formation processing using, for example, a plasma, and the substrate processing apparatus 1 is configured as, for example, a plasma processing apparatus, and more specifically, a plasma chemical vapor deposition (CVD) apparatus.

As shown in FIG. 1, the substrate processing apparatus 1 includes the processing container 11 for processing a wafer 100. The processing container 11 is made of, for example, aluminum and can be airtightly sealed.

A gas supply pipe 13 is provided on an upper portion of the processing container 11. A gas supply device (not shown) is connected to the gas supply pipe 13, and a processing gas used when processing the wafer 100 is supplied.

A shower head 18 that functions as an upper electrode is provided below the gas supply pipe 13. The shower head 18 is provided with a plurality of gas discharge ports 18g that penetrate the shower head 18 in a plate thickness direction.

The processing gas supplied from the gas supply pipe 13 is introduced into the processing container 11 via the gas discharge port 18g. An electrostatic chuck 16 is disposed below the shower head 18 to face the shower head 18.

The electrostatic chuck 16 as a substrate support table horizontally supports the wafer 100 of a processing target in the processing container 11, electrostatically adsorbs the wafer 100, and also functions as a lower electrode.

The electrostatic chuck 16 is supported on a support portion 12 protruding in a cylindrical shape from a bottom wall near a center of the processing container 11 vertically upward. The support portion 12 supports the electrostatic chuck 16 near the center of the processing container 11 at a predetermined distance from the shower head 18 to face the shower head 18 in parallel. With such a structure, the shower head 18 and the electrostatic chuck 16 constitute a pair of parallel flat plate electrodes.

In addition, the electrostatic chuck 16 includes a chuck mechanism for electrostatically adsorbing the wafer 100. The chuck mechanism includes a chuck electrode 16e, a power supply line 45, and a power supply 46. The power supply 46 is connected to the chuck electrode 16e via the power supply line 45. With such a mechanism, a direct current power is supplied from the power supply 46 to the chuck electrode 16e, the upper surface of the electrostatic chuck 16 is electrostatically charged, and the wafer 100 is adsorbed.

In addition, a power supply line 41 is connected to the electrostatic chuck 16. A blocking capacitor 42, an aligner 43, and a high frequency power supply 44 are connected to the power supply line 41. During the plasma processing, a high frequency power of a predetermined frequency is supplied from the high frequency power supply 44 to the electrostatic chuck 16. With such a mechanism, the electrostatic chuck 16 functions as the lower electrode. In addition, with such a configuration, the substrate processing apparatus 1 is configured as, for example, a lower application type plasma processing apparatus.

However, the substrate processing apparatus 1 may be configured as an upper application type plasma processing apparatus by connecting the power supply line 41 having the blocking capacitor 42, the aligner 43, the high frequency power supply 44, and the like to the shower head 18 functioning as the upper electrode.

Alternatively, the substrate processing apparatus 1 may be configured as an upper and lower application type plasma processing apparatus by connecting the power supply line 41 having the blocking capacitor 42, the aligner 43, the high frequency power supply 44, and the like to both the electrostatic chuck 16 and the shower head 18.

An insulator ring 15 is disposed on an outer periphery of the electrostatic chuck 16 to cover peripheral edge portions of the side surface and the bottom surface of the electrostatic chuck 16. An outer peripheral ring 20 is provided above the insulator ring 15 to surround the outer periphery of the electrostatic chuck 16.

The outer peripheral ring 20 is configured to include, for example, a silicon-based material, and during film formation on the wafer 100, to adjust the electric field not to be deflected in a vertical direction, that is, a direction perpendicular to the surface of the wafer 100 at the peripheral edge portion of the wafer 100.

A baffle plate 17 is provided between the insulator ring 15 and the side wall of the processing container 11. The baffle plate 17 has a plurality of gas discharge holes 17e penetrating the baffle plate 17 in the plate thickness direction.

One end portion of an evacuating pipe 9 is connected to a lower portion of the baffle plate 17 of the processing container 11. The other end portion of the evacuating pipe 9 is connected to a vacuum pump 14p that evacuates the atmosphere in the processing container 11.

A region partitioned by the electrostatic chuck 16 and the baffle plate 17 in the processing container 11 and the shower head 18 becomes a plasma processing chamber 31. A region in an upper portion of the processing container 11 partitioned by the shower head 18 is a gas supply chamber 32. A region in a lower portion of the processing container 11 partitioned by the electrostatic chuck 16 and the baffle plate 17 is a gas evacuating chamber 33.

A control unit 40 controls the power supply 46, the aligner 43, the high frequency power supply 44, the gas supply device, and the like.

During the plasma processing of the wafer 100, in accordance with the control of the control unit 40, the wafer 100 of the processing target is placed on the electrostatic chuck 16 and is adsorbed by the chuck mechanism. In addition, the inside of the processing container 11 is vacuumed by the vacuum pump 14p connected to the evacuating pipe 9. When the inside of the processing container 11 reaches a predetermined pressure, the processing gas is supplied to the gas supply chamber 32 from a gas supply device (not shown) and is supplied to the plasma processing chamber 31 via the gas discharge port 18g of the shower head 18.

Further, in accordance with the control of the control unit 40, the plasma is generated in the plasma processing chamber 31 by applying a high frequency voltage to the lower electrode, that is, the electrostatic chuck 16, in a state where the upper electrode, that is, the shower head 18, is grounded. A potential gradient is generated between the plasma and the wafer 100 by a self-bias due to the high frequency voltage on a lower electrode side, and the ions in the plasma are accelerated to the electrostatic chuck 16, and thus, the film formation processing is performed on the wafer 100.

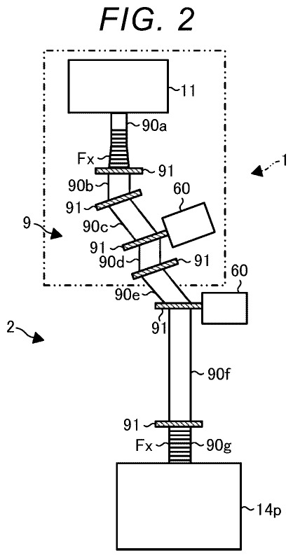

FIG. 2 is a schematic diagram showing an example of a configuration of an evacuating system 2 provided in the substrate processing apparatus 1 according to the embodiment.

As shown in FIG. 2, and as described above, the substrate processing apparatus 1 is provided with the evacuating pipe 9 that connects the processing container 11 and the vacuum pump 14p. The evacuating pipe 9 connects the processing container 11 and the vacuum pump 14p by connecting a plurality of sub-pipes 90 (90a to 90g) to each other. The number of sub-pipes 90 provided in the evacuating pipe 9 and a connection path from the processing container 11 to the vacuum pump 14p may vary depending on the environment in which the substrate processing apparatus 1 is installed.

Each of the sub-pipes 90 is made of, for example, stainless steel, nickel alloy, or the like, and has a flange 91 used for connecting the sub-pipes to each other at each of both ends. The flange 91 has a diameter larger than a pipe diameter of each of the sub-pipes 90 and protrudes in a flange shape from a body portion of the sub-pipe 90.

In addition, some of the sub-pipes 90 have a flexible joint portion Fx. The flexible joint portion Fx is configured in a bellows shape capable of bending and stretching, and is further appropriately used for a movable portion of a predetermined mechanism or the like in order to be matched with a shape of the connection path between the processing container 11 and the vacuum pump 14p, or in order to alleviate an influence of vibration of the vacuum pump 14p or the like.

Among the sub-pipes 90a to 90g, the sub-pipes 90a to 90d are pipe portions that are built in the main body of the substrate processing apparatus 1 and are also referred to as internal device pipes. The sub-pipes 90a to 90d are incorporated into the main body of the substrate processing apparatus 1, for example, from the time of shipment of the substrate processing apparatus 1.

On the other hand, the sub-pipes 90e to 90g are pipe portions disposed on the outside of the main body of the substrate processing apparatus 1 and are also referred to as external device pipes. The sub-pipes 90e to 90g may be appropriately reassembled at the destination according to an installation environment of the substrate processing apparatus 1 or the like and may be connected to the vacuum pump 14p or the like.

When the wafer 100 is plasma-processed in the above-described processing container 11, by-products such as a decomposition product of the plasma-treated processing gas and a film component of a film formation target are generated. These by-products may be deposited in the evacuating pipe 9 in which the plurality of sub-pipes 90a to 90g are combined.

When the deposition film in the evacuating pipe 9 exceeds a predetermined thickness, the deposition film may be peeled off from the inner wall of the evacuating pipe 9 and may damage the vacuum pump 14p and the like. Although measures such as winding a tape heater around a part or the entire evacuating pipe 9 are sometimes taken, it is difficult to completely prevent the deposition of by-products.

Therefore, in the substrate processing apparatus 1 according to the embodiment, one or more film thickness meters 60 capable of measuring the thickness of the deposition film in the evacuating pipe 9 are installed at a predetermined position of the evacuating pipe 9. The film thickness meter 60 monitors the thickness of the deposition film in the evacuating pipe 9, and when the thickness of the deposition film becomes equal to or greater than a predetermined film thickness, exchange work of the sub-pipe 90 in that portion is performed.

In the evacuating pipe 9 between the processing container 11 and the vacuum pump 14p, the film thickness meter 60 is preferably installed at a site where the deposition film is more likely to be formed. As the site where the deposition film is easily formed, for example, a bent portion, a portion having a lower temperature than other portions, and the like are exemplified, and such a site is also referred to as a cold spot.

In addition, in the evacuating pipe 9, as shown in FIG. 2, a portion of the flange 91 provided in each of the sub-pipes 90 is relatively easy to install the film thickness meter 60. The film thickness meter 60 may be installed in the body portion of the sub-pipe 90 instead of the flange 91. However, it is desirable to avoid the installation of the film thickness meter 60 in the flexible joint portion Fx having irregularities in the sub-pipe 90 as much as possible.

### Configuration Example of Film Thickness Meter

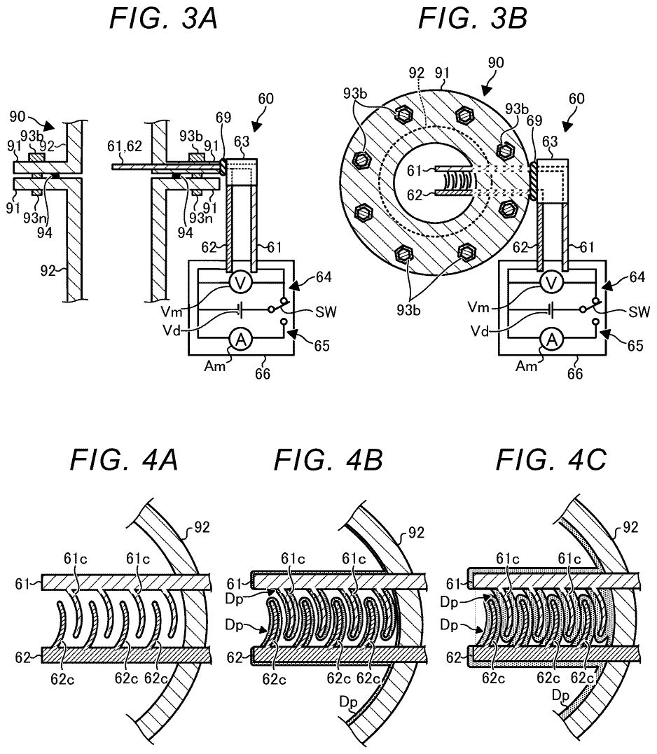

Next, a detailed configuration example of the film thickness meter 60 according to the embodiment will be described with reference to FIGS. 3A to 5.

FIGS. 3A and 3B are schematic diagrams showing an example of the configuration of the film thickness meter 60 according to the embodiment. More specifically, FIG. 3A is the film thickness meter 60 viewed in a cross section in a direction along an extending direction of the sub-pipe 90, and FIG. 3B is the film thickness meter 60 viewed in a cross section in a direction along a radial direction of the sub-pipe 90.

FIGS. 3A and 3B also show a detailed configuration of a connection portion of the sub-pipe 90. As shown in FIGS. 3A and 3B, each of the sub-pipes 90 includes a main body portion 92, which is a body portion of the sub-pipe 90, and a flange 91, which is a connection portion of the sub-pipe 90 with the other sub-pipes 90. A gasket 94 is inserted between the flanges 91 of the sub-pipes 90 connected to each other, and the flanges 91 are fixed to each other by a plurality of bolts 93b and nuts 93n. As a result, the plurality of sub-pipes 90 can be connected to each other in an airtight manner.

The above-described film thickness meter 60 has an electrostatic capacitance sensor 63 and an electrostatic capacitance measuring device 66, and is provided on the flange 91 of a predetermined sub-pipe 90.

The electrostatic capacitance sensor 63 includes, for example, a pair of terminals 61 and 62. In the terminals 61 and 62, the terminal 61 is a plus terminal, and the terminal 62 is a minus terminal. As described above, the terminals 61 and 62 of the film thickness meter 60 have a two-terminal structure. In addition, the terminals 61 and 62 of the film thickness meter 60 are also comb-shaped electrodes having a comb-tooth shape at one end portion, for example, as will be described in detail later.

The terminals 61 and 62 are made of, for example, a conductive material such as stainless steel, aluminum, copper, gold, silver, carbon, and a conductive ceramic. Alternatively, any of the above materials may be nickel-coated.

In addition, one end portion of each of the terminals 61 and 62 having the comb-tooth shape is inserted into the sub-pipe 90 through the flange 91 of the sub-pipe 90. In order to insert the terminals 61 and 62, through-holes provided in the flange 91 may have a diameter of about 1 mm. The other end portions of the terminals 61 and 62 are connected to the electrostatic capacitance measuring device 66.

A seal member 69 such as an O-ring or mortar is provided in a portion of the terminals 61 and 62 penetrating the flange 91. As a result, the airtightness in the sub-pipe 90 can be maintained even when the terminals 61 and 62 penetrate the sub-pipe 90. In addition, with such a configuration, the film thickness meter 60 according to the embodiment can be attached not only to the flange 91 but also to the main body portion 92 of the sub-pipe 90.

The electrostatic capacitance measuring device 66 includes a charging circuit 64 and a constant current discharge circuit 65. A voltage meter Vm is provided in the charging circuit 64, a current meter Am is provided in the constant current discharge circuit 65, and a power supply Vd is connected to the charging circuit 64 and the constant current discharge circuit 65. The charging circuit 64 and the constant current discharge circuit 65 are connected to each other via a switch SW.

FIGS. 4A to 4C are schematic diagrams showing an operation principle of the film thickness meter 60 according to the embodiment.

When the thickness of the deposition film Dp in the evacuating pipe 9 is measured by the film thickness meter 60 according to the embodiment, the charging of the charging circuit 64 of the electrostatic capacitance measuring device 66 and the discharging by the constant current discharge circuit 65 are repeated. When the discharge is performed by the constant current discharge circuit 65, the time required for the discharge changes according to the electrostatic capacitance between the pair of terminals 61 and 62 inserted into the evacuating pipe 9. In the film thickness meter 60 according to the embodiment, the thickness of the deposition film Dp in the evacuating pipe 9 is measured based on the change in the discharge time.

As shown in FIGS. 4A to 4C, when the plasma processing is repeated in the substrate processing apparatus 1, the deposition film Dp is gradually formed to be thick on the inner wall of the sub-pipe 90 in the initial state. Along with this, the deposition film Dp is also formed on the plurality of comb-shaped portions 61c and 62c at one end portion of each of the terminals 61 and 62 inserted into the sub-pipe 90. Thereby, the electrostatic capacitance between the comb-shaped portions 61c and 62c changes according to the thickness of the deposition film Dp formed on the comb-shaped portions 61c and 62c.

For example, when a conductive deposition film Dp such as a film of carbon alone or a film with a high carbon ratio is formed, the thickness of the deposition film Dp increases, the electrostatic capacitance between the comb-shaped portions 61c and 62c decreases, and the time required for the discharge is shortened. On the other hand, when the insulating deposition film Dp such as a tetra eth-oxy silane (TEOS) film is formed, the thickness of the deposition film Dp increases, the electrostatic capacitance between the comb-shaped portions 61c and 62c increases, and the time required for the discharge is prolonged.

More precisely, the electrostatic capacitance between the comb-shaped portions 61c and 62c can be obtained based on the following Equation (1), and the film thickness of the deposition film Dp can be calculated from the obtained electrostatic capacitance according to the film type of the deposition film Dp to be formed in the sub-pipe 90. As a result, it is possible to measure the thickness of the deposition film Dp with an order of several μm.

$$C = I \times ( T 2 - T 1 ) / ( V 1 - V 2 ) \qquad ( 1 )$$

C: Electrostatic capacitance [F]
I: Discharge current [A]
V1: Measurement start voltage [V]
V2: Measurement end voltage [V]
T1: Measurement start time [s]
T2: Measurement end time [s]

The control unit 40 of the substrate processing apparatus 1 controls the film thickness meter 60 configured as described above to acquire the electrostatic capacitance between the comb-shaped portions 61c and 62c, calculates the thickness of the deposition film Dp in the sub-pipe 90 at that time from the acquired electrostatic capacitance, and monitors the thickness. Further, the control unit 40 notifies an administrator or the like of the substrate processing apparatus 1 of the timing when the thickness of the deposition film Dp becomes equal to or greater than a predetermined value. The administrator or the like receives the notification and exchanges at least the corresponding sub-pipe 90 or exchanges one or more sub-pipes 90 including the corresponding sub-pipe 90 as necessary.

The film thickness meter 60 itself may have a processor (not shown) that is independent of the control unit 40 of the substrate processing apparatus 1, and the processor of the film thickness meter 60 may perform, for example, the acquisition of the electrostatic capacitance and the processing up to the calculation of the deposition film Dp based on the electrostatic capacitance. The processor of the film thickness meter 60 can transmit the calculated film thickness of the deposition film Dp to the control unit 40 of the substrate processing apparatus 1 in a timely manner, and the control unit 40 can notify the administrator or the like of the substrate processing apparatus 1 of the calculated film thickness based on this.

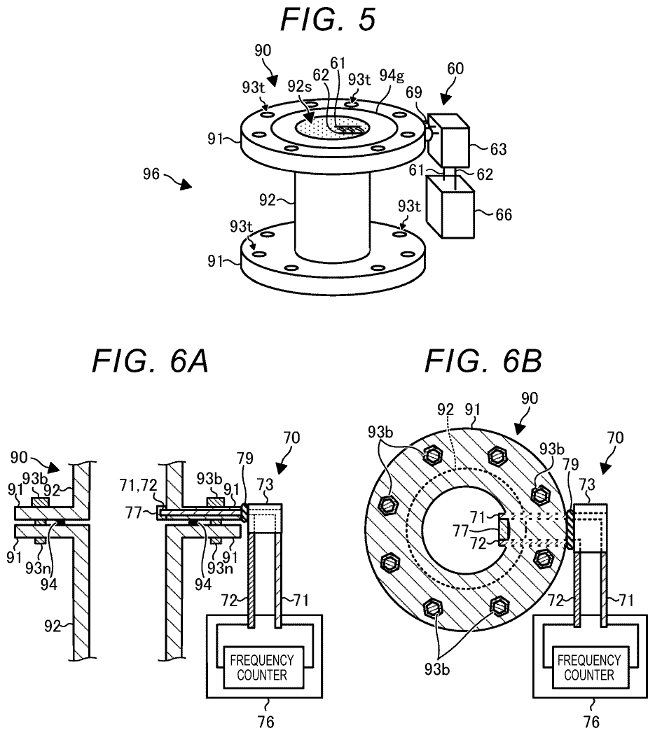

Further, it is preferable that a pipe 96 with a measuring device shown in FIG. 5 is prepared in advance and stocked as the sub-pipe 90 to be exchanged when the deposition film Dp reaches a predetermined thickness.

FIG. 5 is a schematic perspective view showing an example of a configuration of the pipe 96 with a measuring device to which the film thickness meter 60 according to the embodiment is attached.

As shown in FIG. 5, the pipe 96 with a measuring device includes a sub-pipe 90 having flanges 91 at both ends, and a film thickness meter 60 having the electrostatic capacitance sensor 63 and the electrostatic capacitance measuring device 66 attached to the flange 91 of the sub-pipe 90.

The flange 91 of the sub-pipe 90 has a plurality of bolt holes 93t penetrating the flange 91 and has a gasket groove 94g on a connection surface with another flange 91. When the other flange 91 is connected, the gasket 94 is mounted on the gasket groove 94g, and the bolts 93b are inserted into the plurality of bolt holes 93t and are fastened by the nuts 93n.

The terminals 61 and 62 of the electrostatic capacitance sensor 63 are inserted into the sub-pipe 90 through the flange 91 via the seal member 69. Thereby, the terminals 61 and 62 protrude into the sub-pipe 90 from the inner wall 92s of the sub-pipe 90.

By preparing the pipe 96 with a measuring device in advance, the exchange work can be easily performed by a normal exchange procedure of the sub-pipe 90 even when the part of the sub-pipe 90 to which the film thickness meter 60 is attached is exchanged.

### SUMMARY

In the substrate processing apparatus that performs the film formation processing on the wafer, the deposition film may be formed in the evacuating pipe that evacuates the atmosphere in the processing container. In this case, it is preferable to monitor the film thickness of the deposition film in the evacuating pipe, because the evacuating pipe is exchanged before the film thickness reaches a film thickness at which peeling may occur. Therefore, the film thickness meter that measures the film thickness based on a transmittance of laser light or the like, the film thickness meter that measures the film thickness based on the reflected wave of the ultrasonic wave, or the like is being studied.

However, in the film thickness meter using laser light or the like, it is difficult to accurately measure the thickness of the deposition film having light absorption, such as a carbon film. In addition, in the film thickness meter using the ultrasonic wave, the measurement accuracy is not so high in the first place, and only the measurement with an order of several hundred μm can be performed.

According to the film thickness meter 60 of the embodiment, the film thickness meter 60 includes the terminals 61 and 62 whose one end portion is inserted into the evacuating pipe 9, and the electrostatic capacitance measuring device 66 that is connected to the other end portion of the terminals 61 and 62 outside the evacuating pipe 9.

With such a configuration, the deposition film Dp is formed on one end portions of the terminals 61 and 62 inserted into the evacuating pipe 9, and the change in the electrostatic capacitance between the terminals 61 and 62 is measured by the electrostatic capacitance measuring device 66, so that the thickness of the deposition film Dp can be accurately and easily measured. In addition, since the thickness of the deposition film Dp is calculated based on the change in the electrostatic capacitance, it is possible to measure the thickness of the deposition film Dp based on the film type of the deposition film Dp, assuming that the film type of the deposition film Dp is known.

According to the film thickness meter 60 of the embodiment, the terminals 61 and 62 are the comb-shaped electrodes having the plurality of comb-shaped portions 61c and 62c at one end portion. In this way, the measurement accuracy can be improved by forming one end portions of the terminals 61 and 62 in the comb shape.

According to the film thickness meter 60 of the embodiment, the terminals 61 and 62 are inserted into the sub-pipe 90 at the connection portion between the predetermined sub-pipes 90. That is, the terminals 61 and 62 are inserted into the sub-pipe 90 through the flange 91. As a result, the installation of the film thickness meter 60 becomes easy.

According to the film thickness meter 60 of the embodiment, the seal member 69 is provided on the outside of the insertion portions of the terminals 61 and 62 in the evacuating pipe 9. As a result, the airtightness in the evacuating pipe 9 can be maintained.

According to the pipe 96 with a measuring device of the embodiment, the pipe 96 with a measuring device includes the terminals 61 and 62 whose one end portions are inserted into the sub-pipe 90 and the electrostatic capacitance measuring device 66 connected to the other end portions of the terminals 61 and 62 outside the sub-pipe 90. By preparing such a pipe 96 with a measuring device, it is possible to omit the work of attaching the film thickness meter 60 when the sub-pipe 90 is exchanged, and the work of exchanging the sub-pipe 90 can be easily performed in a short time.

### Modified Example 1

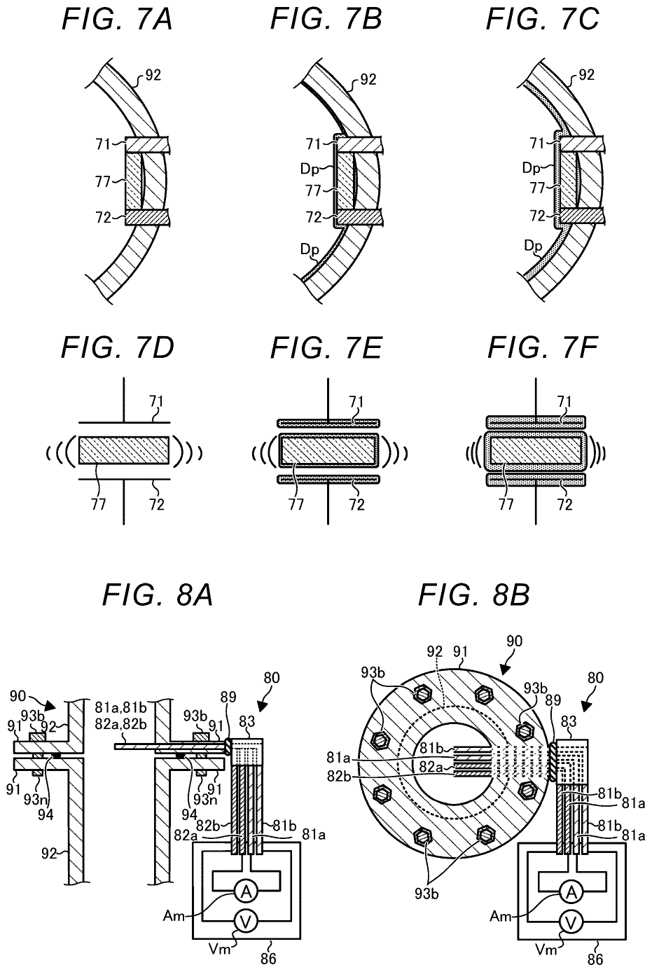

Next, a configuration example of a film thickness meter 70 according to Modified Example 1 of the embodiment will be described with reference to FIGS. 6A to 7F. The film thickness meter 70 of Modified Example 1 is different from the above-described embodiment in that the film thickness meter 70 measures the thickness of the deposition film Dp based on a change in a frequency of an oscillator 77.

In the following drawings, the same reference numerals as in the above-described embodiment may be used for the same configuration as in the above-described embodiment, and the description thereof may be omitted.

FIGS. 6A and 6B are schematic diagrams showing an example of a configuration of the film thickness meter 70 according to Modified Example 1 of the embodiment. More specifically, FIG. 6A is the film thickness meter 70 as viewed in a cross section in a direction along the extending direction of the sub-pipe 90, and FIG. 6B is the film thickness meter 70 as viewed in a cross section in a direction along the radial direction of the sub-pipe 90.

The film thickness meter 70 of Modified Example 1 is provided with the oscillator 77, a frequency sensor 73, and a frequency counter 76, and is provided on the flange 91 of a predetermined sub-pipe 90.

The oscillator 77 is attached to the inner wall of the sub-pipe 90 or the like. The oscillator 77 is, for example, a crystal oscillator that oscillates at a predetermined frequency by using a piezoelectric effect of a crystal.

The frequency sensor 73 includes, for example, a pair of terminals 71 and 72. In the terminals 71 and 72, the terminal 71 is a plus terminal, and the terminal 72 is a minus terminal. The terminals 71 and 72 are made of a conductive material similar to the terminals 61 and 62 provided in the film thickness meter 60 of the above-described embodiment, for example.

In addition, one end portion of each of the terminals 71 and 72 is inserted into the sub-pipe 90 through the flange 91 of the sub-pipe 90, and is connected to the oscillator 77 attached to the inner wall of the sub-pipe 90 or the like. The other end portions of the terminals 71 and 72 are connected to the frequency counter 76.

A seal member 79 is provided in a portion of the terminals 71 and 72 penetrating the flange 91. The seal member 79 of Modified Example 1 is also configured in the same manner as the seal member 69 provided in the film thickness meter 60 of the above-described embodiment by an O-ring, mortar, or the like.

The film thickness meter 70 of Modified Example 1 can be attached not only to the flange 91 but also to the main body portion 92 of the sub-pipe 90.

FIGS. 7A to 7F are schematic diagrams showing an operation principle of the film thickness meter 70 according to Modified Example 1 of the embodiment.

More specifically, FIGS. 7A to 7C show a state where the deposition film Dp is formed in the sub-pipe 90 by the plasma processing in the substrate processing apparatus 1. In addition, FIG. 7D shows a detailed view of the oscillator 77 in FIG. 7A, FIG. 7E shows a detailed view of the oscillator 77 in FIG. 7B, and FIG. 7F shows a detailed view of the oscillator 77 in FIG. 7C.

When the thickness of the deposition film Dp in the sub-pipe 90 is measured by the film thickness meter 70 of Modified Example 1, the oscillator 77 is vibrated at a predetermined frequency by applying a predetermined voltage to the oscillator 77 by a pair of terminals 71 and 72. Further, the pair of terminals 71 and 72 sense a frequency of vibration of the oscillator 77 as a predetermined voltage value. The frequencies sensed by the terminals 71 and 72 are counted by the frequency counter.

As shown in FIGS. 7A to 7C, as the deposition film Dp is formed on the inner wall of the sub-pipe 90 by the plasma processing in the substrate processing apparatus 1, the deposition film Dp is also formed on the surface of the oscillator 77 attached to the inner wall of the sub-pipe 90 and the surfaces of the pair of terminals 71 and 72 that sandwich the oscillator 77, as shown in FIGS. 7D to 7F. Thereby, the frequency of vibration of the oscillator 77 changes.

Here, in the measurement using the oscillator 77 such as the crystal oscillator, the frequency of the vibration of the oscillator 77 decreases as the deposition film Dp becomes thicker, regardless of the film type such as the conductive film or the insulating film. That is, for example, when the conductive deposition film Dp such as a carbon film is formed, the thickness of the deposition film Dp increases, and the frequency of the vibration of the oscillator 77 decreases. Similarly, even when the deposition film Dp having insulating properties, such as a TEOS film, is formed, the thickness of the deposition film Dp increases and the frequency of the vibration of the oscillator 77 decreases.

More precisely, the thickness of the deposition film Dp formed on the surfaces of the terminals 71 and 72 is calculated from the amount of change in the frequency of the vibration of the oscillator 77 based on the following Equation (2).

$$Δ F = - \frac{2 Δ {mnf}_{0}^{2}}{A {μ}_{q}^{1 / 2} {ρ}_{q}^{1 / 2}} \qquad ( 2 )$$

ΔF: Amount of change in frequency of vibration of oscillator
f₀: Base frequency
n: Number of harmonic overtones
A: Area of terminal attached to oscillator
μ_{q}: Elasticity of configuration material of oscillator
ρ_{q}: Density of configuration material of oscillator
Δm: Amount of deposition film formed for unit area of terminal

According to the above-described method, the accuracy of the thickness measurement of the deposition film Dp can be improved by selecting the oscillator 77 that performs oscillation at a high frequency. When the oscillator 77 having a frequency of, for example, 5 MHz is selected as the oscillator 77, it is possible to measure the thickness of the deposition film Dp in the order of angstroms.

The film thickness meter 70 of Modified Example 1 may also be controlled by the control unit 40 of the substrate processing apparatus 1 described above, and the control unit 40 can perform the film thickness calculation and film thickness determination of the deposition film Dp. Alternatively, in the film thickness meter 70 of Modified Example 1, the processor may be provided in the film thickness meter 70 itself, and the film thickness meter 70 may perform the processing up to the film thickness calculation of the deposition film Dp.

In addition, the film thickness meter 70 of Modified Example 1 can also be prepared in advance and stocked by using the pipe with a measuring device to which the film thickness meter 70 is attached.

According to the film thickness meter 70 of Modified Example 1, the film thickness meter 70 includes the terminals 71 and 72 whose one end portions are inserted into the sub-pipe 90, and the frequency counter 76 connected to the other end portions of the terminals 71 and 72 outside the sub-pipe 90.

Even with such a configuration, the deposition film Dp is formed on one end portion of the terminal 71 or 72 inserted into the sub-pipe 90 and to which the oscillator 77 is attached, and the frequency change of the vibration of the oscillator 77 is measured by the frequency counter 76, so that the thickness of the deposition film Dp can be accurately and easily measured. In addition, since the thickness of the deposition film Dp is calculated based on the frequency change of the vibration of the oscillator 77, the thickness of the deposition film Dp can be calculated for various cases regardless of the type of the film.

In addition, by using the oscillator 77 having an appropriate frequency of vibration, it is possible to adjust the measurement accuracy to a desired level.

According to the film thickness meter 70 of Modified Example 1, the same effects as those of the film thickness meter 60 of the above-described embodiment are obtained.

### Modified Example 2

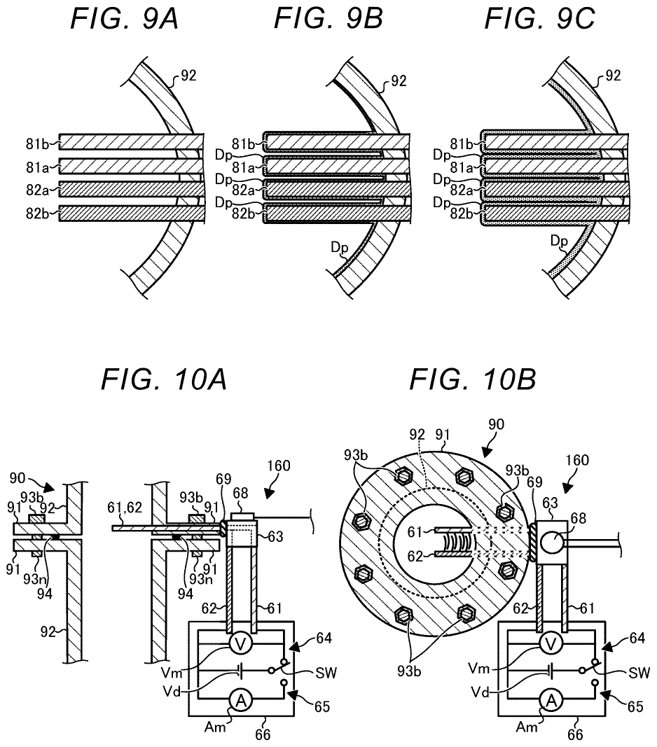

Next, a configuration example of a film thickness meter 80 according to Modified Example 2 of the embodiment will be described with reference to FIGS. 8A to 9C. The film thickness meter 80 of Modified Example 2 is different from the above-described embodiment in that the thickness of the deposition film Dp is measured based on a change in a resistance value between terminals 81b and 82b.

In the following drawings, the same reference numerals as in the above-described embodiment may be used for the same configuration as in the above-described embodiment, and the description thereof may be omitted.

FIGS. 8A and 8B are schematic diagrams showing an example of a configuration of a film thickness meter 80 according to Modified Example 2 of the embodiment. More specifically, FIG. 8A is the film thickness meter 80 as viewed in a cross section in a direction along the extending direction of the sub-pipe 90, and FIG. 8B is the film thickness meter 80 as viewed in a cross section in a direction along the radial direction of the sub-pipe 90.

The film thickness meter 80 of Modified Example 2 has a resistance value sensor 83 and a resistance value measuring device 86, and is provided on the flange 91 of a predetermined sub-pipe 90.

The resistance value sensor 83 includes, for example, two pairs of terminals 81a and 82a, and terminals 81b and 82b. In the terminals 81a, 81b, 82a, and 82b, the terminals 81a and 82a that are paired with each other are a plus terminal and a minus terminal, respectively, and the terminals 81b and 82b that are paired with each other are a plus terminal and a minus terminal, respectively.

As described above, the terminals 81a, 81b, 82a, and 82b have a four-terminal structure and are made of a conductive material similar to the terminals 61 and 62 provided in the above-described embodiment of the film thickness meter 60, for example.

In addition, one end portions of the terminals 81a, 81b, 82a, and 82b are inserted into the sub-pipe 90 through the flange 91 of the sub-pipe 90. The other end portions of the terminals 81a, 81b, 82a, and 82b are connected to the resistance value measuring device 86.

A seal member 89 is provided in the penetrating portions of the terminals 81a, 81b, 82a, and 82b to the flanges 91. The seal member 89 of Modified Example 2 is also configured in the same manner as the seal member 69 of the film thickness meter 60 of the above-described embodiment by an O-ring, a mortar, or the like.

The film thickness meter 80 of Modified Example 2 can be attached not only to the flange 91 but also to the main body portion 92 or the like of the sub-pipe 90.

The resistance value measuring device 86 is configured as, for example, a multimeter or the like including a current meter Am and a voltage meter Vm. The current meter Am of the resistance value measuring device 86 is connected to the terminals 81a and 82a, and the voltage meter Vm is connected to the terminals 81b and 82b.

The current meter Am and the voltage meter Vm may be connected to a common terminal, and thus, a two-terminal structure having a pair of terminals as in the above-described embodiment can be provided instead of the terminals 81a, 81b, 82a, and 82b having the four-terminal structure. However, by adopting the four-terminal structure, it is possible to separate a wiring through which a current flows from a wiring for measuring a voltage, and more accurate measurement is possible.

FIGS. 9A to 9C are schematic diagrams showing an operation principle of the film thickness meter 80 according to Modified Example 2 of the embodiment.

When the thickness of the deposition film Dp in the sub-pipe 90 is measured by the film thickness meter 80 of Modified Example 2, a current is caused to flow through the pair of terminals 81a and 82a, and a resistance value between the pair of terminals 81b and 82b is measured by the voltage meter Vm.

As shown in FIGS. 9A to 9C, the deposition film Dp is also formed in the terminal 81a, 81b, 82a, and 82b as the deposition film Dp is formed on the inner wall of the sub-pipe 90 by the plasma processing in the substrate processing apparatus 1. Thereby, the resistance value between the terminals 81a, 81b, 82a, and 82b, that is, from the terminal 81b to the terminal 82b changes.

For example, when the conductive deposition film Dp such as a carbon film is formed, the thickness of the deposition film Dp increases, and the resistance value between the terminals 81a, 81b, 82a, and 82b decreases. On the other hand, for example, when the deposition film Dp having insulating properties, such as a TEOS film, is formed, the thickness of the deposition film Dp increases, and the resistance value between the terminals 81a, 81b, 82a, and 82b increases.

More precisely, the thickness of the deposition film Dp formed on the surfaces of the terminals 81a, 81b, 82a, and 82b is calculated from the amount of change in the resistance value between the terminals 81a, 81b, 82a, and 82b based on the following Equation (3).

$$R = \frac{ρ}{t} \frac{L}{W} \qquad ( 3 )$$

R: Resistance
ρ: Resistivity
t: Thickness of deposition film
L: Length of deposition film
W: Width of deposition film

At this time, L/W in the above Equation (3) is a numerical value that depends on a surface area of the terminals 81a, 81b, 82a, and 82b and is constant. Therefore, a thickness t of the deposition film Dp can be calculated. With such a method, it is possible to measure the thickness of the deposition film Dp on the order of several μm.

The film thickness meter 80 of Modified Example 2 may also be controlled by the control unit 40 of the substrate processing apparatus 1 described above, and the control unit 40 can perform the film thickness calculation and the film thickness determination of the deposition film Dp.

Alternatively, also in the film thickness meter 80 of Modified Example 2, the processor may be provided in the film thickness meter 80 itself, and the film thickness meter 80 may perform the processing up to the film thickness calculation of the deposition film Dp.

In addition, the film thickness meter 80 of Modified Example 2 can also be prepared in advance and stocked by using the pipe with a measuring device to which the film thickness meter 80 is attached.

According to the film thickness meter 80 of Modified Example 2, the terminals 81a, 81b, 82a, and 82b whose one end portions are inserted into the inside of the sub-pipe 90, and the resistance value measuring device 86 connected to the other end portions of the terminals 81a, 81b, 82a, and 82b outside the sub-pipe 90 are provided.

Even with such a configuration, the deposition film Dp is formed on one end portions of the terminals 81a, 81b, 82a, and 82b inserted into the sub-pipe 90, and the change in the resistance value between the terminals 81a, 81b, 82a, and 82b is measured by the resistance value measuring device 86, so that the thickness of the deposition film Dp can be accurately and easily measured. In addition, since the thickness of the deposition film Dp can be calculated based on the change in the resistance value between the terminals 81a, 81b, 82a, and 82b, the thickness of the deposition film Dp can be calculated for various cases regardless of the type of the film.

In addition, there is no need for other structures or the like associated with the terminals 81a, 81b, 82a, and 82b, and the device configuration can be simplified. Therefore, the film thickness meter 80 is easy to attach and handle, has excellent maintainability, and can be reduced in size.

According to the film thickness meter 80 of Modified Example 2, the terminals 81a, 81b, 82a, and 82b have the four-terminal structure. As a result, noise during measurement can be reduced to further improve the measurement accuracy.

According to the film thickness meter 80 of Modified Example 2, the same effects as those of the film thickness meter 60 of the above-described embodiment are obtained.

### Modified Example 3

Next, a configuration example of a film thickness meter 160 according to Modified Example 3 of the embodiment will be described with reference to FIGS. 10A and 10B. The film thickness meter 160 of Modified Example 3 is different from the above-described embodiment in that the film thickness meter 160 includes a vibrator 68.

In the following drawings, the same reference numerals as in the above-described embodiment may be used for the same configuration as in the above-described embodiment, and the description thereof may be omitted. In addition, an example in a case where the film thickness meter 60 according to the above-described embodiment is used as a base will be described with reference to the following drawings.

FIGS. 10A and 10B are schematic diagrams showing an example of a configuration of the film thickness meter 160 according to Modified Example 3 of the embodiment. More specifically, FIG. 10A is the film thickness meter 160 viewed in a cross section in a direction along the extending direction of the sub-pipe 90, and FIG. 10B is the film thickness meter 160 viewed in a cross section in a direction along the radial direction of the sub-pipe 90.

The film thickness meter 160 of Modified Example 3 includes the vibrator 68 in addition to the same configuration as the film thickness meter 60 of the above-described embodiment. The vibrator 68 is provided such as to be, for example, in contact with the electrostatic capacitance sensor 63 of the film thickness meter 160, and is capable of giving vibration to the electrostatic capacitance sensor 63.

As the vibrator 68, for example, a general vibrator such as a ball type vibrator that generates vibration by rotation of an eccentric weight or a piston type vibrator that generates vibration by vertical movement of a piston can be used.

The control unit 40 of the substrate processing apparatus 1 vibrates the vibrator 68 of the film thickness meter 160 as appropriate to remove the deposition film Dp formed on the terminals 61 and 62 of the electrostatic capacitance sensor 63. Thereby, the terminals 61 and 62 of the electrostatic capacitance sensor 63 can be maintained in a substantially initial state. The control unit 40 can cause the vibrator 68 to vibrate at a predetermined timing based on the integrated time of the plasma processing in the substrate processing apparatus 1, for example, at a cycle shorter than the exchange cycle of the sub-pipe 90.

The processor may be provided in the film thickness meter 160 of Modified Example 3, and the film thickness meter 160 may control the vibrator 68.

In addition, the film thickness meter 160 of Modified Example 3 can also be prepared in advance and stocked by using the pipe with a measuring device to which the film thickness meter 160 is attached.

According to the film thickness meter 160 of Modified Example 3, the vibrator 68 for vibrating the terminals 61 and 62 is provided. Thereby, it is possible to prevent a decrease in the measurement accuracy of the film thickness meter 160 due to, for example, a change over time.

According to the film thickness meter 160 of Modified Example 3, the same effects as those of the film thickness meter 60 of the above-described embodiment are obtained.

In the above-described Modified Example 3, an example in which the vibrator 68 is attached to the film thickness meter 60 according to the above-described embodiment is described. Moreover, the configuration of Modified Example 3 can also be applied to the film thickness meters 70 and 80 of Modified Examples 1 and 2 described above.

### Modified Example 4

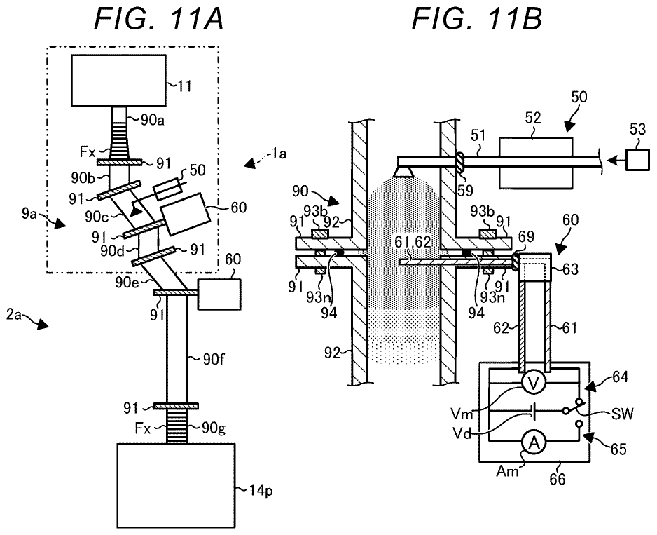

Next, a substrate processing apparatus 1a of Modified Example 3 of the embodiment will be described with reference to FIGS. 11A and 11B. The substrate processing apparatus 1a of Modified Example 3 is different from the above-described embodiment in that a cleaning unit 50 is provided on upstream of the film thickness meter 60 in the evacuating pipe 9a.

In the following drawings, the same reference numerals as in the above-described embodiment may be used for the same configuration as in the above-described embodiment, and the description thereof may be omitted. In addition, in the following drawings, an example in which the substrate processing apparatus 1a of Modified Example 4 has the film thickness meter 60 of the embodiment will be described.

FIGS. 11A and 11B are schematic diagrams showing an example of a configuration of the cleaning unit 50 according to Modified Example 4 of the embodiment. More specifically, FIG. 11A is a schematic diagram showing an example of a configuration of the evacuating system 2a provided in the substrate processing apparatus 1a of Modified Example 4, and FIG. 11B is the cleaning unit 50 as viewed in a cross section in a direction along the extending direction of the sub-pipe 90.

As shown in FIG. 11A, one or more film thickness meters 60 are also installed in the evacuating pipe 9a of the substrate processing apparatus 1a of Modified Example 4. In addition, the cleaning unit 50 is provided at a predetermined position of the evacuating pipe 9a.

The cleaning unit 50 is preferably provided, for example, in the vicinity of the film thickness meter 60 installed in the evacuating pipe 9a and on the upstream of the film thickness meter 60. In addition, when a plurality of film thickness meters 60 are installed in the evacuating pipe 9a, the cleaning unit 50 can be provided further on the upstream of the film thickness meter 60 located at the most upstream of the evacuating pipe 9a.

As shown in FIG. 11B, the cleaning unit 50 includes a waveguide 51 and a plasma source 52.

One end portion of the waveguide 51 penetrates the main body portion 92 of the sub-pipe 90, for example, via a seal member 59, and is inserted into the sub-pipe 90. The other end portion of the waveguide 51 is connected to a cleaning gas supply source 53 outside the sub-pipe 90.

The plasma source 52 is provided in the waveguide 51 between the sub-pipe 90 and the cleaning gas supply source 53. The plasma source 52 generates, for example, a microwave to generate plasma the cleaning gas supplied into the waveguide 51 from the cleaning gas supply source 53. The plasma of the cleaning gas is introduced into the sub-pipe 90 through the waveguide 51 to remove the deposition film Dp in the evacuating pipe 9a including the sub-pipe 90 provided with the cleaning unit 50.

As described above, by disposing the cleaning unit 50 on the upstream of the predetermined film thickness meter 60, the deposition film Dp formed on the terminals 61 and 62 of the film thickness meter 60 is also removed when the deposition film Dp in the evacuating pipe 9a is removed.

Therefore, as the cleaning gas, an appropriate gas can be selected from various gases according to the film type of the deposition film Dp. As an example, when the deposition film Dp is a carbon film or the like, oxygen, hydrogen, nitrogen trifluoride (NF₃), or a mixed gas of some of these can be used as the cleaning gas.

As described above, the cleaning unit 50 is configured as a remote plasma processing apparatus that performs cleaning processing by generating, for example, remote plasma.

The cleaning unit 50 and the film thickness meter 60 are preferably provided in, for example, different sub-pipes 90. As a result, the attachment and handling of each sub-pipe 90 can be easily performed, and the maintainability can be improved. The cleaning unit 50 and the film thickness meter 60 may be provided in the same sub-pipe 90.

The control unit of the substrate processing apparatus 1a of Modified Example 4 controls the cleaning unit 50 to clean the inside of the evacuating pipe 9a and the terminals 61 and 62 of the film thickness meter 60 at predetermined timings based on the integrated time of the plasma processing in the substrate processing apparatus 1a.

According to the substrate processing apparatus 1a of Modified Example 4, the waveguide 51 of which one end portion is inserted into the evacuating pipe 9a on the upstream of the terminals 61 and 62, and the other end portion is connected to the cleaning gas supply source 53 outside the evacuating pipe 9a, and the plasma source 52 that is provided on the waveguide 51 outside the evacuating pipe 9a are provided. As a result, the cleaning of the evacuating pipe 9a can be performed in a timely manner to remove the deposition film Dp, and the frequency of exchange of the sub-pipe 90 and the film thickness meter 60 can be reduced.

The substrate processing apparatus 1a according to Modified Example 4 has the same effects as the substrate processing apparatus 1 of the above-described embodiment.

In Modified Example 4 described above, an example in which the cleaning unit 50 is attached to the substrate processing apparatus 1a including the film thickness meter 60 according to the embodiment described above is described. Moreover, the configuration of Modified Example 4 can also be applied to the film thickness meters 70 and 80 of Modified Examples 1 and 2 described above.

In addition, in the above-described embodiment and Modified Examples 1 to 4, the configurations are applied to the substrate processing apparatus 1, 1a, and the like configured as the plasma CVD apparatus. However, the configuration of the above-described embodiment and Modified Examples 1 to 4 can be applied to various substrate processing apparatuses in which the deposition film may be formed in the evacuating pipe.

As application examples of the configuration of the embodiment and Modified Examples 1 to 4, for example, a thermal CVD apparatus that forms a film on a wafer by accelerating a chemical reaction by heat instead of plasma, a plasma etching apparatus that performs etching processing on a wafer, a plasma ashing apparatus or an ozone ashing apparatus that performs ashing removal of a photoresist film formed on a wafer by plasma or ozone, and the like are listed.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing apparatus comprising:
a processing container that processes a substrate;
a gas supply pipe that supplies a processing gas to the processing container;
a pump that evacuates an atmosphere in the processing container;
an evacuating pipe that connects the processing container and the pump;
one or more pairs of conductive terminals, a first end portion of each of which is inserted into the evacuating pipe; and
a measuring device that is connected to a second end portion of a conductive terminal outside the evacuating pipe, wherein the measuring device is one of an electrostatic capacitance measuring device, a frequency counter, or a resistance value measuring device.

2. The substrate processing apparatus according to claim 1, wherein
the conductive terminal is a comb-shaped electrode having a plurality of comb-shaped portions at the first end portion, and
the measuring device is an electrostatic capacitance measuring device.

3. The substrate processing apparatus according to claim 1, wherein
the conductive terminal includes an oscillator attached to the first end portion, and
the measuring device is a frequency counter.

4. The substrate processing apparatus according to claim 1, wherein
the conductive terminal has four terminals, and
the measuring device is a resistance value measuring device.

5. The substrate processing apparatus according to claim 1, further comprising:
a waveguide wherein a first end portion of the waveguide is inserted into the evacuating pipe on upstream of the conductive terminal and a second end portion of the waveguide is connected to a cleaning gas supply source outside the evacuating pipe; and
a plasma source provided in the waveguide outside the evacuating pipe.

6. The substrate processing apparatus according to claim 1, wherein
the evacuating pipe has a plurality of sub-pipes, and
the conductive terminal is inserted into a sub-pipe at a connection portion between the sub-pipe and another sub-pipe among the plurality of sub-pipes.

7. The substrate processing apparatus according to claim 6, wherein
each of the plurality of sub-pipes has a flange at the connection portion, and
the conductive terminal is inserted into the sub-pipe through the flange of the sub-pipe.

8. The substrate processing apparatus according to claim 1, further comprising:
a seal member provided outside an insertion portion of the conductive terminal in the evacuating pipe.

9. The substrate processing apparatus according to claim 1, wherein
the conductive terminal is inserted into the evacuating pipe between the processing container and the pump, the evacuating pipe being an internal device pipe disposed in the substrate processing apparatus.

10. An apparatus used in a substrate processing apparatus including a processing container that processes a substrate, and a pump that evacuates an atmosphere in the processing container,
the apparatus comprising:
a pipe;
a measuring device that is one of an electrostatic capacitance measuring device, a frequency counter, or a resistance value measuring device; and
one or more pairs of conductive terminals, a first end portion of each of which is inserted into the pipe, wherein
the pipe connects the processing container and the pump, and
the measuring device is connected to a second end portion of a conductive terminal outside the pipe.

11. The apparatus according to claim 10, wherein
the conductive terminal is a comb-shaped electrode having a plurality of comb-shaped portions at the first end portion, and
the measuring device is an electrostatic capacitance measuring device.

12. The apparatus according to claim 9, wherein
the conductive terminal includes an oscillator attached to the first end portion, and
the measuring device is a frequency counter.

13. The apparatus according to claim 9, wherein
the conductive terminal has four terminals, and
the measuring device is a resistance value measuring device.

14. The apparatus according to claim 9, wherein
the pipe has a plurality of sub-pipes, and
the conductive terminal is inserted into a sub-pipe at a connection portion between the sub-pipe and another sub-pipe among the plurality of sub-pipes.

15. The apparatus according to claim 14, wherein
each of the plurality of sub-pipes has a flange at the connection portion, and
the conductive terminal is inserted into the sub-pipe through the flange of the sub-pipe.

16. The apparatus according to claim 9, wherein
the conductive terminal is inserted into the pipe between the processing container and the pump, the pipe being an internal device pipe disposed in the substrate processing apparatus.

17. A measuring method of a deposition film formed on an inner wall of an evacuating pipe that connects a processing container that processes a substrate and a pump that evacuates an atmosphere in the processing container, the measuring method comprising:
measuring a resistance value between one or more pairs of conductive terminals, a first end portion of each of which is inserted into the evacuating pipe; and
determining a thickness of the deposition film based on the resistance value.

18. The measuring method according to claim 17, further comprising:
determining a thickness of the deposition film is equal to or greater than a predetermined value; and
exchanging the evacuating pipe, or
introducing remote plasma of a cleaning gas from a plasma source provided in a waveguide outside the evacuating pipe to the waveguide of which a first end portion is inserted into the evacuating pipe and a second end portion is connected to a supply source of the cleaning gas.

19. The measuring method according to claim 16, further comprising:
measuring the resistance value using a multimeter comprising a current meter and a voltage meter connected respectively to the conductive terminals.

20. The measuring method according to claim 16, wherein the thickness of the deposition film is determined using at least one of a resistivity, a length, or a width of the deposition film.
